(19) United States
(12) Patent Application Publication
(10) Pub. No.: US 2021/0028410 A1
(43) Pub. Date: Jan. 28, 2021

(54) METHOD FOR MANUFACTURING DISPLAY DEVICE, MOTHER BOARD, AND DISPLAY DEVICE

(71) Applicant: SHARP KABUSHIKI KAISHA, Sakai City, Osaka (JP)

(72) Inventors: AKIHIRO MATSUI, Sakai City, Osaka (JP); TAKESHI HIRASE, Sakai City, Osaka (JP); YOSHINOBU MIYAMOTO, Sakai City, Osaka (JP); TOHRU SONODA, Sakai City, Osaka (JP); HISAO OCHI, Sakai City, Osaka (JP); TOHRU SENOO, Sakai City, Osaka (JP); JUMPEI TAKAHASHI, Sakai City, Osaka (JP); TAKASHI OCHI, Sakai City, Osaka (JP)

(21) Appl. No.: 17/041,946

(22) PCT Filed: Mar. 28, 2018
(86) PCT No.: PCT/JP2018/012768

§ 371 Date: Sep. 25, 2020

(51) Int. Cl. H01L 51/56; H01L 51/52

(52) U.S. Cl. CPC H01L 51/56; H01L 27/3246; H01L 2227/323; H01L 51/5253

(57) ABSTRACT

A method for manufacturing a display device, includes: forming a thin film transistor layer; forming a light-emitting element layer; and forming a sealing layer, wherein the display device includes: a display region; and a frame region being a non-display region formed on an outer side of the display region, during forming the thin film transistor layer, a mask spacer is formed on an outer side of a cutting surface corresponding to an end face of the frame region, the mask spacer on which a deposition mask is placed, during forming the sealing layer, at least one inorganic film is formed through use of the deposition mask, and the at least one inorganic film covers the display region, and is formed on an inner side of the cutting surface.

### TECHNICAL FIELD

The present invention relates to a method for manufacturing a display device, a mother substrate, and a display device.

### BACKGROUND ART

PTL 1 discloses a film formation deposition mask that forms a display device pattern region in a part of each substrate region on a mother substrate on which a plurality of substrate regions constituting the display device are collected.

### CITATION LIST

### Patent Literature

PTL 1: brochure of WO “WO 2007/102247 (international publication on Sep. 13, 2007)”

### SUMMARY OF INVENTION

### Technical Problem

(a) of FIG. 8 is a cross-sectional view illustrating an internal schematic configuration of a chemical vapor deposition (CVD) device for forming an inorganic film IO through use of a deposition mask DM. ST is a reference symbol for a stage of the CVD device, and GB is a reference symbol for a glass substrate. A plurality of openings are formed in the deposition mask DM as illustrated in (b) of FIG. 8, and the inorganic film IO is formed on the glass substrate GB through the openings as illustrated in (c) of FIG. 8.

Deflection is caused to the deposition mask DM due to its own weight as illustrated in FIG. 9. Thus, when the deposition mask DM is attached or detached, the deposition mask DM is not evenly brought into contact with the glass substrate GB.

FIG. 10 is a view for explaining a conventional problem in forming an inorganic film 105a and/or an inorganic film 105b through use of the deposition mask DM that forms a sealing inorganic film. In this drawing, MB is a reference symbol for a mother substrate. The mother substrate MB includes a backplane (BP) substrate 101, and an organic protection film 102 is formed above the BP substrate 101. OP is a reference symbol for an outer panel region of the mother substrate MB. DP is a reference symbol for a cutting surface (or a cutting position). PF is a reference symbol for a frame region. Further, 104, 105c, 108, 109, and 110 are reference symbols for a bank, a flattening organic film, a second electrode, a deposition layer, and a PS/EC, respectively. Note that PE and EC are abbreviated forms of a photo spacer and an edge cover, respectively.

As illustrated in FIG. 10, when an edge portion of the deposition mask DM and the frame region PF of a display device 200 are locally brought into contact with each other, a scratch such as a dent is formed in some cases. For example, when deflection as described above is caused to any one of the BP substrate 101 and the deposition mask DM, the edge portion of the deposition mask DM is firstly brought into contact with the organic protection film 102 at the time of contact. In a worse case, a scratch such as a dent is formed. With this, a yield rate and reliability may be degraded.

### Solution to Problem

A method for manufacturing a display device according one aspect of the present invention includes forming a thin film transistor layer, forming a light-emitting element layer, and forming a sealing layer. The display device includes a display region and a frame region being a non-display region formed on an outer side of the display region. During forming the thin film transistor layer, a mask spacer is formed on an outer side of a cutting surface corresponding to an end face of the frame region, the mask spacer on which a deposition mask is placed. During forming the sealing layer, at least one inorganic film is formed through use of the deposition mask. The at least one inorganic film covers the display region, and is formed on an inner side of the cutting surface.

A mother substrate according to one aspect of the present invention is obtained by collecting a plurality of substrate regions constituting a display device, the display device including a display region and a frame region being a non-display region formed on an outer side of the display region. A mask spacer is formed at least on an outer side of a cutting surface corresponding to an end face of the frame region, the mask spacer on which a deposition mask is placed.

A display device according to one aspect of the present invention includes a display region, a frame region being a non-display region formed on an outer side of the display region, and an opening formed on an inner side of the display region. A mask spacer is formed on an outer side of the opening, the mask spacer on which a deposition mask is placed.

### Advantageous Effects of Invention

A yield rate and reliability of the display device can be improved, and the durable number of times of the deposition mask can be increased.

### BRIEF DESCRIPTION OF DRAWINGS

FIG. 1(a) is a top view illustrating a schematic configuration of a display device according to an embodiment of the present invention. FIG. 1(b) is a cross-sectional view illustrating a schematic configuration of the display device.

FIG. 2 is a cross-sectional view illustrating a schematic configuration of a display device according to a first embodiment of the present invention.

FIG. 3 is a cross-sectional view illustrating a schematic configuration of a display device according to a second embodiment of the present invention.

FIG. 4(a) is a top view illustrating a schematic configuration of a display device according to a third embodiment of the present invention. FIG. 4(b) is a view illustrating an example of an outer appearance configuration of a deposition mask (one unit). FIG. 4(c) is a view illustrating a state of the display device after an inorganic film is formed through use of a deposition mask and panels are divided from each other.

FIGS. 5(a) to 5(c) are views for explaining variations of methods for arranging mask spacers.

FIGS. 6(a) and 6(b) are views each illustrating an arrangement example of the mask spacers.

FIGS. 7(a) and 7(b) are views each illustrating an arrangement example of the mask spacers.

FIG. 8(a) is a cross-sectional view illustrating an internal schematic configuration of a CVD device for forming an inorganic film through use of a deposition mask. FIG. 8(b) is a top view illustrating a structure of the deposition mask. FIG. 8(c) is a top view illustrating a state of a mother substrate after an inorganic film is formed through use of the deposition mask.

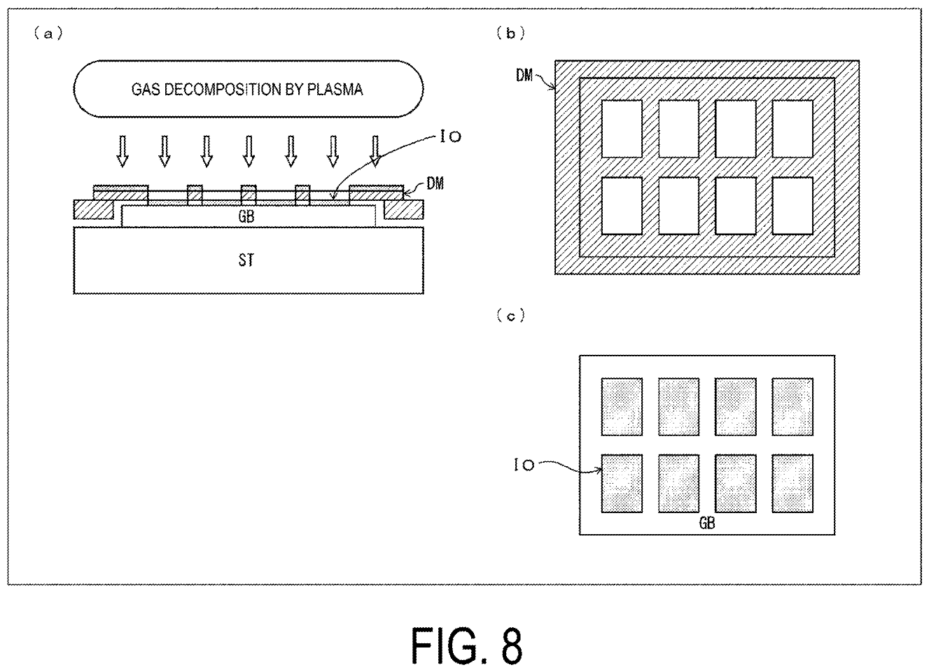

FIG. 9 is a diagram for explaining a conventional problem in forming an inorganic film through use of the deposition mask.

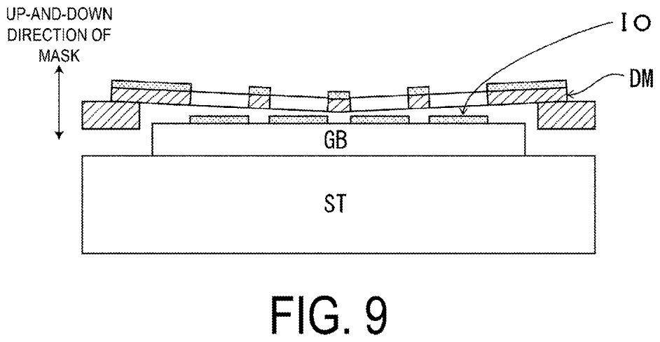

FIG. 10 is a diagram for explaining a conventional problem in forming an inorganic film through use of the deposition mask.

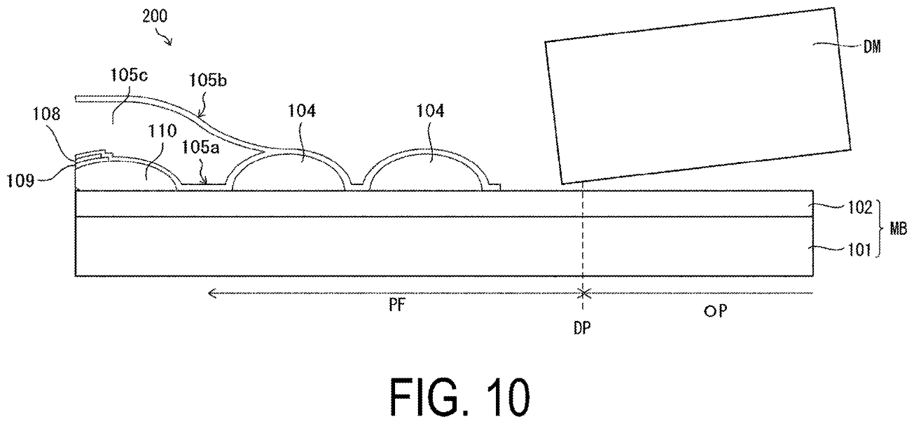

### DESCRIPTION OF EMBODIMENTS

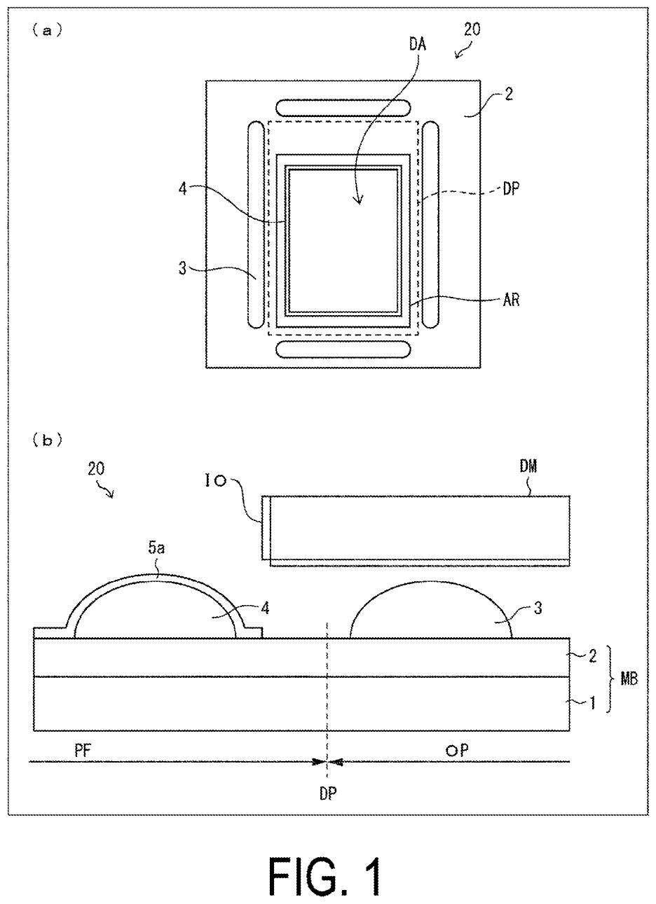

(a) of FIG. 1 is a top view illustrating a schematic configuration of a display device 20 according to an embodiment of the present invention. Further, (b) of FIG. 1 is a cross-sectional view illustrating a schematic configuration of the display device 20. As illustrated in those drawings, a mother substrate MB of the display device 20 includes a backplane (BP) substrate 1, and an organic protection film 2 is formed above the BP substrate 1.

As illustrated in (a) of FIG. 1, a bank 4, which controls a formation position of a flattening organic film 5c formed in a thin film transistor layer formation process described later, is formed in a peripheral edge of a display region DA. Note that AR is a reference symbol for an inorganic film formation region and DP is a reference symbol for a cutting surface (or a cutting position).

As illustrated in (b) of FIG. 1, in the display device 20 according to the present embodiment, a mask spacer 3 on which a deposition mask DM is placed is formed at least on an outer side (outer panel region OP) of a cutting surface DP corresponding to an end face of a frame region PF. The mask spacer 3 is formed of a material similar to at least one of the material of the bank 4 and the material of the flattening organic film 5c. More specifically, the material of the mask spacer 3 is a polyimide resin or an acrylic-based resin. The mask spacer 3 is formed by a photolithography process for a photosensitive resin or printing.

(b) of FIG. 1 illustrates a state in which a first inorganic film 5a is formed through use of the deposition mask DM. The deposition mask DM is metal (invar or the like) having a thickness of approximately from 100 μm to 200 μm. The deposition mask DM is subjected to cleaning through use of gas.

A cross-sectional shape of the mask spacer 3 may be any one of a trapezoidal shape and a rectangular shape in addition to a dome shape illustrated in (b) of FIG. 1. A height of the mask spacer 3 (a height from a surface of the organic protection film 2 to a top portion of the mask spacer 3) is approximately 4 μm in the present embodiment, and is only required to fall within a range from 2 μm to 20 μm.

The mother substrate MB is a substrate obtained by collecting a plurality of substrate regions constituting the display device 20 that includes the display region DA, the frame region PF being a non-display region formed on the outer side of the display region DA, and the outer panel region OP. On the outer side (the outer panel region OP) of the cutting surface DP corresponding to the end face of the frame region PF, the mask spacer 3 on which the deposition mask DM is placed is formed.

Further, in the present embodiment, the first inorganic film 5a is formed through use of the deposition mask DM. IO is a reference symbol for an inorganic film adhering to an edge portion of the deposition mask DM at the time of forming an inorganic film.

In the display device 20 according to the present embodiment, the mask spacer 3 is provided directly below the deposition mask DM. Thus, a force is more likely to be applied to the mask spacer 3 at the time of contact. The edge portion of the deposition mask DM is less likely to be brought into contact with the BP substrate 1 (or with the organic protection film 2), or is softly brought into contact. This reduces scratches, and thus improvement of a yield rate and reliability of the display device 20 can be achieved. Further, this also reduces local wear at the edge portion of the deposition mask DM is suppressed, and thus increase of the durable number of times and cost reduction of the deposition mask DM can be expected.

A method for manufacturing a display device according to the present embodiment includes the thin film transistor layer formation process for forming a thin film transistor, a light-emitting element layer formation process for forming a light-emitting element layer, and a sealing layer formation process for forming a sealing layer.

Further, the thin film transistor layer formation process includes a spacer formation process for forming the mask spacer 3 on which the deposition mask DM is placed, at least on the outer side of the cutting surface DP corresponding to the end face of the frame region PF.

Further, the sealing layer formation process includes an inorganic film formation process for forming at least one layer of an inorganic film (the first inorganic film 5a and/or a second inorganic film 5b described later) through use of the deposition mask DM. Further, the inorganic film covers the display region DA, and is formed on an inner side of the cutting surface DP.

### First Embodiment

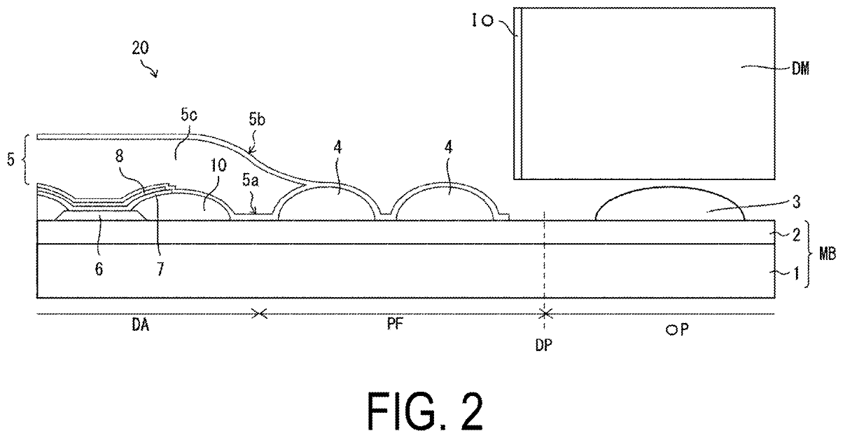

As illustrated in FIG. 2, the display device 20 according to the present embodiment includes the mother substrate MB, the mask spacer 3, the bank 4, a sealing layer 5, a first electrode 6, a light-emitting layer 7, a second electrode 8, and a PS/EC 10. The mother substrate MB includes the BP substrate 1, and the organic protection film 2 is formed above the BP substrate 1. IO is a reference symbol for an inorganic film adhering to the edge portion of the deposition mask DM. The display device 20 includes the display region DA, the frame region PF being a non-display region formed on the outer side of the display region DA, and the outer panel region OP on the outer side of the frame region PF.

Further, the sealing layer 5 is a layer obtained by layering the first inorganic film 5a, the flattening organic film 5c, and the second inorganic film 5b in this order. In the display device 20 according to the present embodiment, the mask spacer 3 on which the deposition mask DM is placed is formed at least on the outer side (outer panel region OP) of the cutting surface DP corresponding to the end face of the frame region PF. FIG. 2 illustrates a state in which the second inorganic film 5b is formed through use of the deposition mask DM. The first inorganic film 5a is formed as described above, and the second inorganic film 5b in the present embodiment is formed. In both cases, the same deposition mask DM is used.

In the display device 20 according to the present embodiment, the mask spacer 3 is provided directly below the deposition mask DM. Thus, a force is more likely to be applied to the mask spacer 3 at the time of contact. The edge portion of the deposition mask DM is less likely to be brought into contact with the BP substrate 1, or is softly brought into contact. This reduces scratches, and thus improvement of a yield rate and reliability of the display device 20 can be achieved. Further, this also reduces local wear at the edge portion of the deposition mask DM is suppressed, and thus increase of the durable number of times and cost reduction of the deposition mask DM can be expected.

### Second Embodiment

A display device 20a according to the present embodiment is different from the mode described above in that, at the time of forming the flattening organic film 5c included in the sealing layer 5, a flattening organic film 3a is formed as a mask spacer used for forming the second inorganic film 5b.

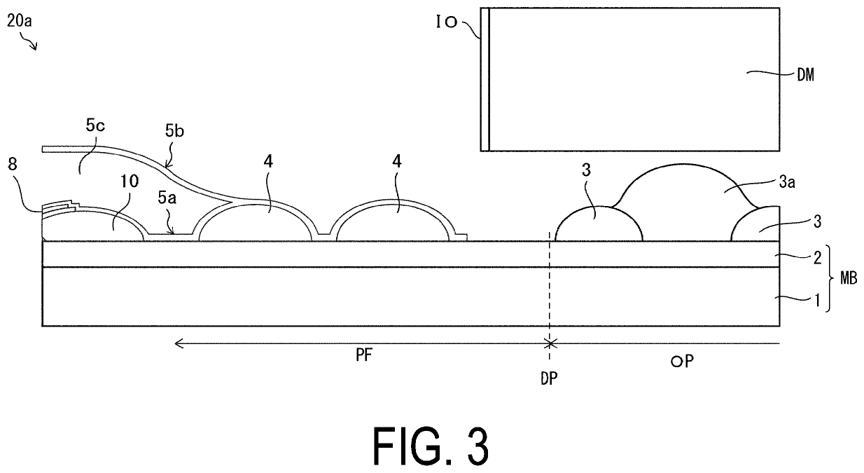

As illustrated in FIG. 3, the flattening organic film 3a in the present embodiment is formed between two mask spacers 3. Specifically, the flattening organic film 3a is held in contact with a plurality of the mask spacers formed outside of the frame region PF (the outer panel region OP). The flattening organic film 3a functions as a mask spacer used for forming the second inorganic film 5b.

A height of the flattening organic film 3a (a height from the surface of the organic protection film 2 to a top portion of the flattening organic film 3a) is approximately 10 μm in the present embodiment, and is only required to fall within a range from 2 μm to 20 μm.

In the display device 20a according to the present embodiment, the flattening organic film 3a is provided directly below the deposition mask DM. Thus, a force is more likely to be applied to the flattening organic film 3a at the time of contact. The edge portion of the deposition mask DM is less likely to be brought into contact with the BP substrate 1, or is softly brought into contact. This reduces scratches, and thus improvement of a yield rate and reliability of the display device 20 can be achieved. Further, this also reduces local wear at the edge portion of the deposition mask DM is suppressed, and thus increase of the durable number of times and cost reduction of the deposition mask DM can be expected.

### Third Embodiment

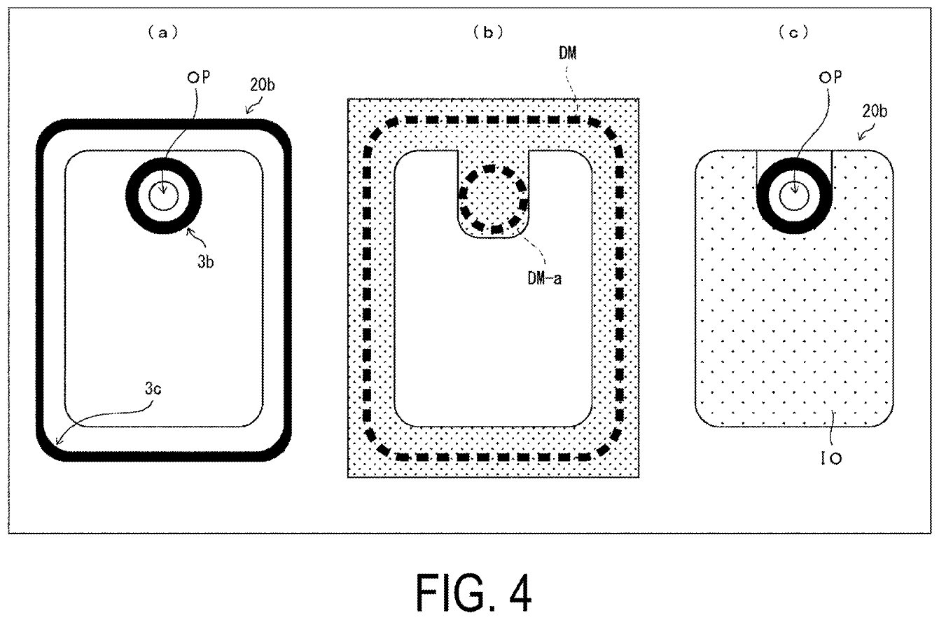

In a display device 20b according to the present embodiment, as illustrated in (a) of FIG. 4, an opening OP is formed on an inner side of the display region. In the thin film transistor layer formation process described above, a mask spacer 3b in a toroidal shape is formed on an outer side of the opening OP. Further, a mask spacer 3c in a substantially rectangular shape is formed in a periphery of the display device 20b.

Further, in the sealing layer formation process described above, the deposition mask DM having a mask protrusion (protrusion) DM-a that covers the opening OP illustrated in (b) of FIG. 4 is placed on the mask spacer 3b and the mask spacer 3c. The inorganic film IO is formed on a side close to the display region with respect to the opening OP, as illustrated in (c) of FIG. 4.

The inorganic film IO is formed through use of the deposition mask DM, and division is performed. After that, as illustrated in (c) of FIG. 4, a state in which the mask spacer 3b in a toroidal shape is left in a periphery of the opening OP is obtained. Note that, in the present embodiment, the mask spacer 3b is provided in conformity with the opening OP. The mask spacer may be provided in conformity with a notched portion or the like.

### EXAMPLE

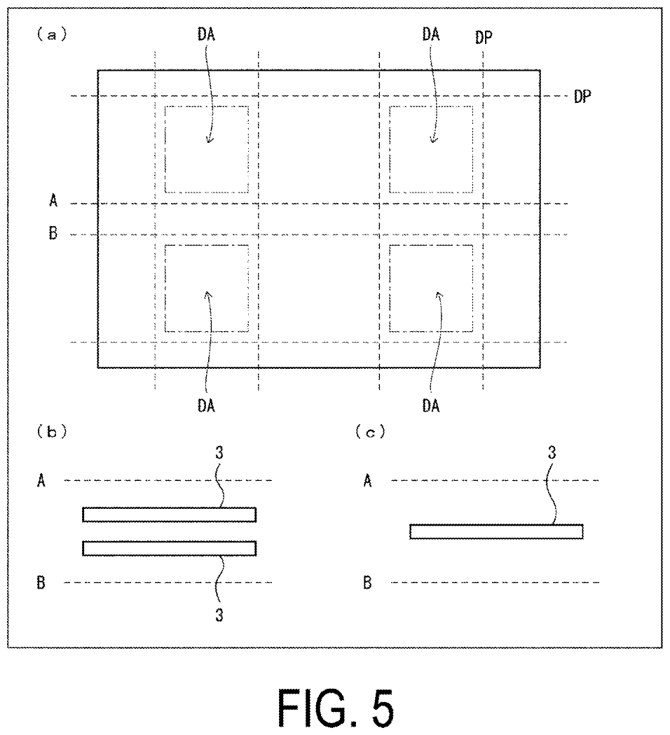

Next, with reference to (a) to (c) of FIG. 5, description is made on variations of methods for arranging the mask spacers. In (a) of FIG. 5, DA is a reference symbol for a display region, and DP is a reference symbol for a cutting surface (line). The mask spacers are only required to be formed on the outer sides of the two upper and lower cutting lines (DP) or on the outer sides of the two right and left cutting lines (DP).

As illustrated in (b) of FIG. 4, the mask spacer 3 may be arranged independently on each of the outer sides of the cutting lines A and B of the upper and lower display regions DA. As illustrated in (c) of FIG. 4, the one mask spacer 3 may be shared by the upper and lower display regions DA.

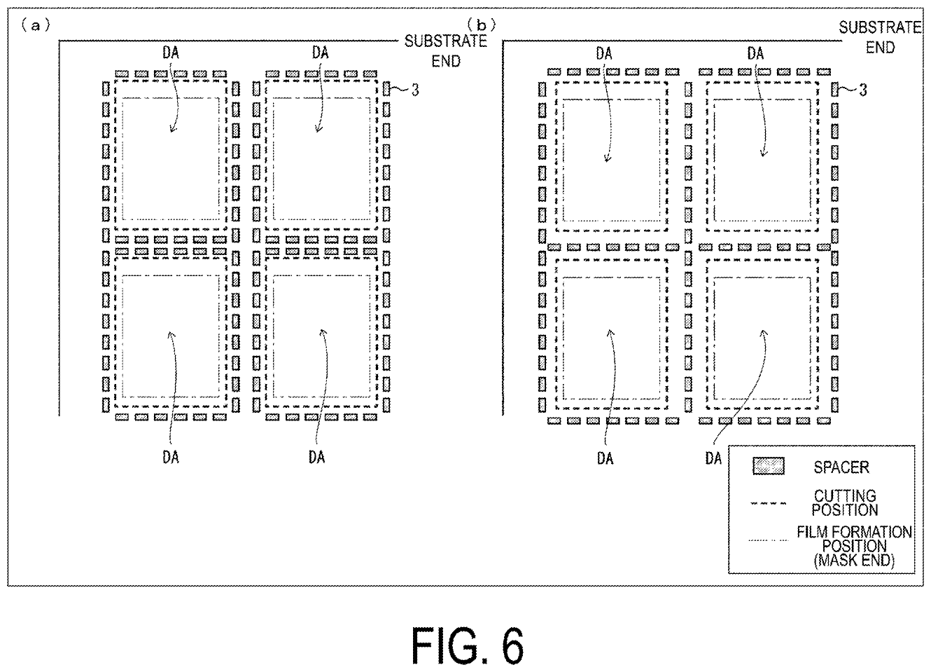

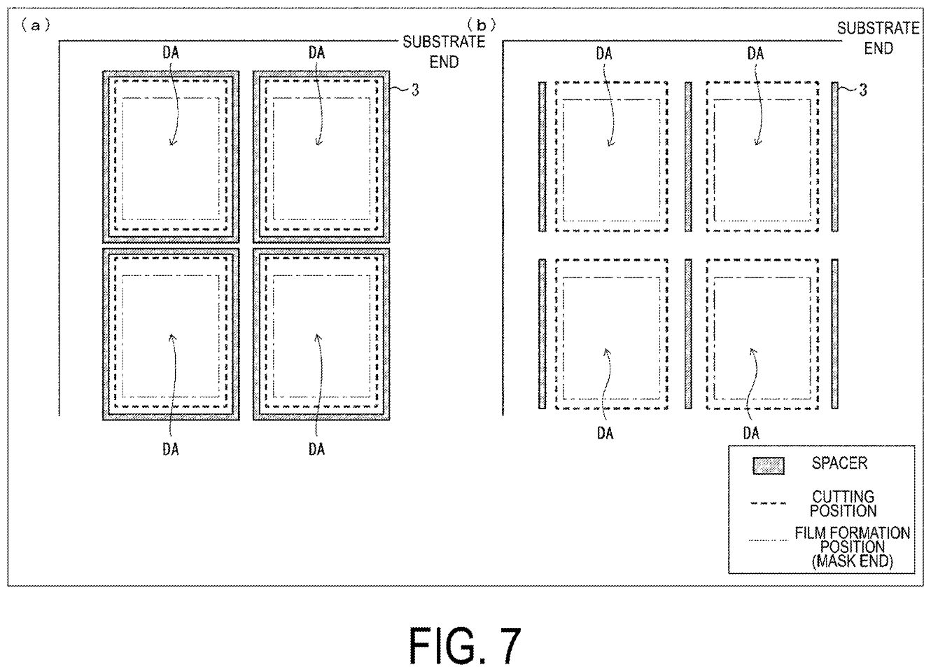

Next, with reference to FIGS. 6 and 7, description is made on arrangement examples of the mask spacers. In the example illustrated in (a) of FIG. 6, the plurality of mask spacers 3 are formed on the outer side of the division position surrounding a periphery of the display region DA.

In the example illustrated in (a) of FIG. 6, the mask spacers 3, which are arranged in two lines, are formed correspondingly to the upper and lower (or right and left) display regions DA. However, in the example illustrated in (b) of FIG. 6, the mask spacers 3 in one line are shared by the upper and lower (or right and left) display regions DA.

In the example illustrated in (a) of FIG. 7, the substantially-rectangular mask spacers 3 are formed to surround the periphery of the display region DA. Further, (b) of FIG. 7 illustrates an example in which the mask spacers 3 are formed on at least the outer sides of the two sides of the display region DA, which face each other (in the right-and-left direction).

Note that, in the examples illustrated in FIG. 6, the plurality of mask spacers 3, which are divided finely, are arranged in lines. In the examples illustrated in FIG. 7, the plurality of mask spacers 3 are formed continuously in lines.

### Supplement

An electro-optical element (an electro-optical element whose luminance and transmittance are controlled by an electric current) that is provided in a display device according to the present embodiment is not particularly limited thereto. Examples of the display device according to the present embodiment include an organic electro luminescence (EL) display provided with an organic light emitting diode (OLED) as an electro-optical element, an inorganic EL display provided with an inorganic light emitting diode as an electro-optical element, and a quantum dot light emitting diode (QLED) display provided with a QLED as an electro-optical element.

### First Aspect

A method for manufacturing a display device according to a first aspect of the present invention, including:

forming a thin film transistor layer;

forming a light-emitting element layer; and

forming a sealing layer,

wherein the display device includes:

a display region; and

a frame region being a non-display region formed on an outer side of the display region,

during forming the thin film transistor layer, a mask spacer is formed on an outer side of a cutting surface corresponding to an end face of the frame region, the mask spacer on which a deposition mask is placed,

during forming the sealing layer, at least one inorganic film is formed through use of the deposition mask, and

the at least one inorganic film covers the display region, and is formed on an inner side of the cutting surface.

### Second Aspect

The method for manufacturing a display device according to the first aspect, for example,

wherein the sealing layer is a layer obtained by layering a first inorganic film, a flattening organic film, and a second inorganic film in this order, and

the at least one inorganic film corresponds to the first inorganic film and the second inorganic film.

### Third Aspect

The method for manufacturing a display device according to the second aspect, for example,

wherein the deposition mask is used for forming the first inorganic film and the second inorganic film.

### Fourth Aspect

The method for manufacturing a display device according to the second aspect, for example,

wherein the mask spacer is formed of a material similar to at least one of a material of a bank and a material of the flattening organic film, the bank controlling a formation position of the flattening organic film formed during forming the thin film transistor layer.

### Fifth Aspect

The method for manufacturing a display device according to the second aspect or the third aspect, for example,

wherein, when the flattening organic film included in the sealing layer is formed, the flattening organic film is formed as a mask spacer used for forming the second inorganic film.

### Sixth Aspect

The method for manufacturing a display device according to the fifth aspect, for example,

wherein the flattening organic film is held in contact with a plurality of the mask spacers formed outside of the frame region.

### Seventh Aspect

The method for manufacturing a display device according to any one of the first aspect to the sixth aspect, for example,

wherein one or more of the plurality of mask spacers are provided at least on outer sides of two sides of the display region, the two sides facing each other.

### Eighth Aspect

The method for manufacturing a display device according to any one of the first aspect to the sixth aspect, for example,

wherein, when a plurality of the display devices are provided, the mask spacer is formed between the plurality of display devices.

### Ninth Aspect

The method for manufacturing a display device according to any one of the first aspect to the eighth aspect, for example,

wherein an opening is formed on an inner side of the display region in the display device,

during forming the thin film transistor layer, the mask spacer is formed on an outer side of the opening, and

during forming the sealing layer, the deposition mask including a protrusion covering the opening is placed on the mask spacer, and an inorganic film is formed on a side close to the display region with respect to the opening.

### Tenth Aspect

A mother substrate according to a tenth aspect of the present invention, the mother substrate obtained by collecting a plurality of substrate regions constituting a display device, the display device including a display region and a frame region being a non-display region formed on an outer side of the display region,

wherein a mask spacer is formed at least on an outer side of a cutting surface corresponding to an end face of the frame region, the mask spacer on which a deposition mask is placed.

### Eleventh Aspect

A display device, including:

a display region;

a frame region being a non-display region formed on an outer side of the display region; and

an opening formed on an inner side of the display region,

wherein a mask spacer is formed on an outer side of the opening, the mask spacer on which a deposition mask is placed.

### Additional Items

The present invention is not limited to each of the embodiments described above, and various modifications may be made within the scope of the claims. Embodiments obtained by appropriately combining technical approaches disclosed in each of the different embodiments also fall within the technical scope of the present invention. Moreover, novel technical features can be formed by combining the technical approaches disclosed in the embodiments.

### REFERENCE SIGNS LIST

3 Mask spacer

3a Flattening organic film

5a First inorganic film

5b Second inorganic film

5c Flattening organic film

20 Display device

20a Display device

20b Display device

DA Display region

DP Cutting surface

DM Deposition mask

DM-a Mask protrusion (protrusion)

MB Mother substrate

PF Frame region

OP Outer panel region

IO Inorganic film

1. A method for manufacturing a display device, comprising:
forming a thin film transistor layer;
forming a light-emitting element layer; and
forming a sealing layer,
wherein the display device includes:
a display region; and
a frame region being a non-display region formed on an outer side of the display region,
during forming the thin film transistor layer, a mask spacer is formed on an outer side of a cutting surface corresponding to an end face of the frame region, the mask spacer on which a deposition mask is placed,
during forming the sealing layer, at least one inorganic film is formed through use of the deposition mask, and
the at least one inorganic film covers the display region, and is formed on an inner side of the cutting surface.

2. The method for manufacturing a display device according to claim 1,
wherein the sealing layer is a layer obtained by layering a first inorganic film, a flattening organic film, and a second inorganic film in this order, and
the at least one inorganic film corresponds to the first inorganic film and the second inorganic film.

3. The method for manufacturing a display device according to claim 2,
wherein the deposition mask is used for forming the first inorganic film and the second inorganic film.

4. The method for manufacturing a display device according to claim 2,
wherein the mask spacer is formed of a material similar to at least one of a material of a bank and a material of the flattening organic film, the bank controlling a formation position of the flattening organic film formed during forming the thin film transistor layer.

5. The method for manufacturing a display device according to claim 2,
wherein, when the flattening organic film included in the sealing layer is formed, the flattening organic film is formed as a mask spacer used for forming the second inorganic film.

6. The method for manufacturing a display device according to claim 5,
wherein the flattening organic film is held in contact with a plurality of the mask spacers formed outside of the frame region.

7. The method for manufacturing a display device according to claim 1,
wherein one or more of the plurality of mask spacers are provided at least on outer sides of two sides of the display region, the two sides facing each other.

8. The method for manufacturing a display device according to claim 1,
wherein, when a plurality of the display devices are provided, the mask spacer is formed between the plurality of display devices.

9. The method for manufacturing a display device according to claim 1,
wherein an opening is formed on an inner side of the display region in the display device,
during forming the thin film transistor layer, the mask spacer is formed on an outer side of the opening, and
during forming the sealing layer, the deposition mask including a protrusion covering the opening is placed on the mask spacer, and an inorganic film is formed on a side close to the display region with respect to the opening.

10. A mother substrate obtained by collecting a plurality of substrate regions constituting a display device, the display device including a display region and a frame region being a non-display region formed on an outer side of the display region,
wherein a mask spacer is formed at least on an outer side of a cutting surface corresponding to an end face of the frame region, the mask spacer on which a deposition mask is placed.

11. (canceled)
